(19) United States
(12) Patent Application Publication
(10) Pub. No.: US 2020/0310499 A1
(43) Pub. Date: Oct. 1, 2020

(54) DISPLAY DEVICE INCLUDING A SHIELD LAYER AND A MANUFACTURING METHOD THEREOF

(71) Applicant: SAMSUNG DISPLAY CO., LTD., YONGIN-SI (KR)

(72) Inventors: Yung Bin Chung, Yongin-si (KR); Yeoung Keol Woo, Seongnam-si (KR); Seung Wook Kwon, Hwaseong-si (KR)

(21) Appl. No.: 16/749,555

(22) Filed: Jan. 22, 2020

(30) Foreign Application Priority Data
Mar. 27, 2019 (KR) 10-2019-0034937

(51) Int. Cl. G06F 1/18; G02B 1/04; G06F 1/16; G02B 1/14

(52) U.S. Cl. CPC G06F 1/182; G02B 1/04; G02B 2207/121; G02B 1/14; G06F 1/1609

(57) ABSTRACT

A display device is provided including a substrate including a first organic layer and a first barrier layer. A shield layer is disposed between the first organic layer and the first barrier layer, and the shield layer includes a metal.

### CROSS-REFERENCE TO RELATED APPLICATION

This application claims priority under 35 U.S.C. § 119 to Korean Patent Application No. 10-2019-0034937 filed in the Korean Intellectual Property Office on Mar. 27, 2019, the disclosure of which is incorporated by reference herein in its entirety.

### TECHNICAL FIELD

The present invention relates to a display device, and more particularly, it relates to a display device including a shield layer and a manufacturing method thereof.

### DISCUSSION OF RELATED ART

A display device, such as an organic light emitting device or a liquid crystal display device, includes a substrate on which various components are formed. A substrate of the display device may be glass, plastic, or the like.

However, a glass substrate is heavy and prone to breakage. Thus it has limitations in portability and use in a large screen display device. It is also difficult to apply the glass substrate to a flexible display device because it may be damaged due to external impact.

Plastic substrates have many advantages over the glass substrate, such as increased portability, safety, and relatively light weight. In addition, plastic substrates can be manufactured by deposition or printing, which can reduce manufacturing costs.

However, in a display device including the plastic substrate, the plastic substrate adheres to the carrier substrate during manufacture, and a process of separating the plastic substrate from the carrier substrate is required.

### SUMMARY

According to an exemplary embodiment of the present invention, a display device is provided including a substrate including a first organic layer and a first barrier layer. A shield layer is disposed between the first organic layer and the first barrier layer, and the shield layer includes a metal.

According to an exemplary embodiment of the present invention, the shield layer has a thickness of about 300 Å to about 6000 Å.

According to an exemplary embodiment of the present invention, the shield layer includes Al, TiN, Ti, Mo, and/or Cu.

According to an exemplary embodiment of the present invention, the first organic layer includes polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and/or an ethylene-vinyl alcohol copolymer.

According to an exemplary embodiment of the present invention, the first barrier layer includes SiOx, SiNx, a-Si, a-SiC, and/or Al₂O₃.

According to an exemplary embodiment of the present invention, the shield layer overlaps an entire surface of the first organic layer.

According to an exemplary embodiment of the present invention, the shield layer has a lattice shape, and at least a portion of the first organic layer does not overlap the shield layer.

According to an exemplary embodiment of the present invention, the substrate further includes a second organic layer that is disposed on the first barrier layer, and a second barrier layer that is disposed on the second organic layer.

According to an exemplary embodiment of the present invention, the second organic layer includes polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and/or an ethylene-vinyl alcohol copolymer. The second barrier includes SiOx, SiNx, a-Si, a-SiC, and/or Al₂O₃.

According to an exemplary embodiment of the present invention, a display device is provided including a substrate including a first organic layer and a first barrier layer. A display layer is disposed on the substrate. A shield layer is disposed between the first organic layer and the first barrier layer. The shield layer includes a metal oxide, and a thickness of the shield layer is about 300 Å to about 450 Å.

According to an exemplary embodiment of the present invention, the shield layer includes ITO, IZO, IZTO, ATO, AZO, GZO, FTO, ZTO, ZnO, FZO, and/or IGZO.

According to an exemplary embodiment of the present invention, the first organic layer includes polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and/or an ethylene-vinyl alcohol copolymer. The first barrier layer includes SiOx, SiNx, a-Si, a-SiC, and/or Al₂O₃.

According to an exemplary embodiment of the present invention, the shield layer overlaps an entire surface of the first organic layer.

According to an exemplary embodiment of the present invention, the shield layer has a lattice shape, and at least a portion of the first organic layer does not overlap the shield layer.

According to an exemplary embodiment of the present invention, a second organic layer is disposed on the first barrier layer, and a second barrier layer is disposed on the second organic layer.

According to an exemplary embodiment of the present invention, a method for manufacturing a display device is provided including forming a first organic layer on a carrier substrate. A shield layer is disposed on the first organic layer. A first barrier layer is disposed on the shield layer. The carrier substrate is separated from the first organic layer, and the shield layer includes a metal or a metal oxide.

The method for manufacturing the display device of claim 16, wherein the shield layer includes a metal, and a thickness of the shield layer is about 300 Å to about 6000 Å.

According to an exemplary embodiment of the present invention, the shield layer includes a metal oxide, and a thickness of the shield layer is about 300 Å to about 450 Å.

According to an exemplary embodiment of the present invention, in the separation of the carrier substrate and the first organic layer, a laser irradiation process is not carried out.

According to an exemplary embodiment of the present invention, the forming of the first barrier layer on the shield layer comprises carrying out a plasma-enhanced chemical vapor deposition (PECVD) process.

### BRIEF DESCRIPTION OF THE FIGURES

The above and other features and aspects of the present invention will become more apparent from the following detailed description of the exemplary embodiments taken in conjunction with the accompanying drawings, in which:

FIG. 1 is a cross-sectional view illustrating a display device, according to an exemplary embodiment of the present invention;

FIG. 2 is a cross-sectional view illustrating a comparative display device;

FIG. 3 is a graph illustrating adhesion measurements between a display device and the carrier substrate at various steps in a process for manufacturing the display device, according to a comparative example;

FIG. 4 is a graph illustrating adhesion measurements of display devices including shield layers of varied thickness and materials, according to exemplary embodiments of the present invention;

FIG. 5 is a cross-sectional view illustrating a process for separating the display device from the carrier substrate according to the comparative example shown in FIG. 2;

FIG. 6 is cross-sectional view illustrating the display device of FIG. 1 attached to a carrier substrate during a manufacturing process, according to an exemplary embodiment of the present invention;

FIG. 7 is a cross-sectional view illustrating a process for separating the carrier substrate from the display device, according to an exemplary embodiment of the present invention;

FIG. 8 is a cross-sectional view illustrating a display device according to an exemplary embodiment of the present invention;

FIG. 9 is a cross-sectional view illustrating the display device of FIG. 8 attached to a carrier substrate, according to an exemplary embodiment of the present invention;

FIG. 10 and FIG. 11 are cross-sectional views illustrating a display device according to exemplary embodiments of the present invention; and

FIG. 12 and FIG. 13 are cross-sectional views illustrating display devices according to exemplary embodiments of the present invention.

### DETAILED DESCRIPTION OF THE EMBODIMENTS

In the following detailed description and accompanying figures, exemplary embodiments of the present invention are shown and described. Those of ordinary skill in the art will realize that the exemplary embodiments included herein may be modified in various different ways without departing from the spirit or scope of the present invention.

Accordingly, the drawings and description may be regarded as illustrative in nature and need not be restrictive. Like reference numerals may refer to like elements throughout the specification and drawings.

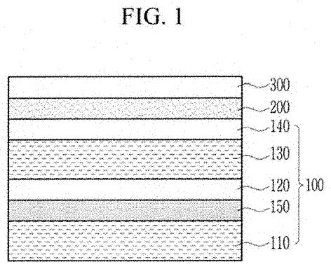

Further, in the drawings, a size and thickness of elements may be exaggerated for better understanding and ease of description, but the present invention is not limited thereto. FIG. 1 schematically illustrates a cross-section of a display device according to an exemplary embodiment of the present invention. Referring to FIG. 1, a display device according to the present exemplary embodiment includes a substrate 100, a low temperature polycrystalline silicon (LTPS) layer 200 disposed on the substrate 100, and a display layer 300 disposed on the LTPS layer 200. The LTPS layer 200 includes a gate line, a data line, a semiconductor layer, a transistor, and the like. The display layer 300 may refer to a layer formed by evaporation and thin film encapsulation, and may include a light emitting element layer and an encapsulation layer that encapsulates the light emitting element layer. The light emitting element layer may include an organic emission layer, or may include an inorganic material such as quantum dots.

Referring to FIG. 1, the substrate 100 may be multi-layered. For example, the substrate 100 includes a first organic layer 110, a second organic layer 130, a first barrier layer 120 disposed between the first organic layer 110 and the second organic layer 130, a second barrier layer 140 disposed between the second organic layer 130 and the LTPS layer 200, and a shield layer 150 disposed between the first organic layer 110 and the first barrier layer 120.

For example, the substrate 100, according to the present exemplary embodiment of the present invention, includes two organic layers and two barrier layers alternately stacked, and a shield layer 150 is disposed between the first organic layer 110 and the first barrier layer 120.

The first organic layer 110 may include at least one of polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and an ethylene-vinyl alcohol copolymer. The first organic layer 110 may have a thickness of about 5 μm to about 20 μm.

The first barrier layer 120 may include at least one of SiOx, SiNx, a-Si, a-SiC, and Al₂O₃. Here, x may be an integer from 1 to 4. The first barrier layer 120 prevents a material of the first organic layer 110 from affecting the LTPS layer 200 disposed above.

The second organic layer 130 may include at least one of polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and an ethylene-vinyl alcohol copolymer. A thickness of the second organic layer 130 may be about 5 μm to about 20 μm.

The second barrier layer 140 may include at least one of SiOx, SiNx, a-Si, a-SiC, and Al₂O₃. The second barrier layer 140 prevents a material of the second organic layer 130 from affecting the LTPS layer 200 disposed above.

The substrate 100 includes the first organic layer 110 and the second organic layer 130 and thus it may be flexible.

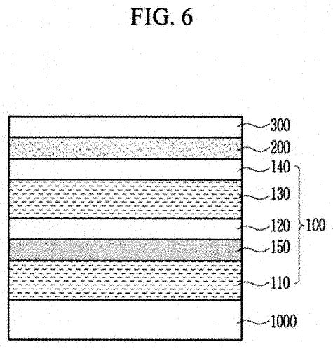

The shield layer 150 is disposed between the first organic layer 110 and the first barrier layer 120. The shield layer 150 may prevent an increase of adherence between the carrier substrate 1000 (shown in FIG. 6) and the display device during a manufacturing process of the display device, and accordingly, the display device can be easily detached from the carrier substrate 1000 by the inclusion of the shield layer 150.

The substrate 100, according to the present exemplary embodiment of the present invention, is flexible and thus the substrate 100 is placed on the carrier substrate 1000 made of glass prior to further manufacture. After the process is carried out, the substrate 100 needs to be detached from the carrier substrate. However, when adherence between the carrier substrate and the substrate 100 of the display device is strong, detachment cannot be easily carried out.

However, in the display device according to the exemplary embodiment of the present invention, the shield layer 150 is included in the substrate 100 such that the carrier substrate 1000 and the substrate can be easily detached from each other.

The shield layer 150 may include a metal and/or a metal oxide. For example, the shield layer 150 may include at least one of Al, TiN, Ti, Mo, Cu, ITO, IZO, IZTO, ATO, AZO, GZO, FTO, ZTO, ZnO, FZO, and IGZO, but this is not restrictive. The shield layer 150 may have a thickness of about 300 Å to about 6000 Å. For example, the shield layer 150 may have a thickness of about 300 Å to about 450 Å to prevent the entire thickness of the substrate 100 from being increased.

In a process for stacking the substrate 100 of the display device on the carrier substrate 1000, adherence between the substrate 100 and the carrier substrate 1000 is significantly increased when the first barrier layer 120 is formed after the first organic layer 110 is stacked. This is because the first barrier layer 120 is manufactured through a plasma-enhanced chemical vapor deposition (PECVD) process, and plasma used in the process affects an adherence characteristic between the first organic layer 110 and the carrier substrate. For example, the plasma used in the process for forming the first barrier layer 120 changes an interface characteristic between the first organic layer 110 and the carrier substrate, and thus increases adherence of the substrate 100 with the carrier substrate 1000.

However, when the shield layer 150 that includes a metal or a metal oxide is disposed between the first organic layer 110 and the first barrier layer 120, as in the display device according to an exemplary embodiment of the present invention, the plasma that affects the first organic layer 110 is blocked by the shield layer 150. Accordingly, an increase of adherence between the carrier substrate 1000 and the substrate 100 of the display device can be prevented.

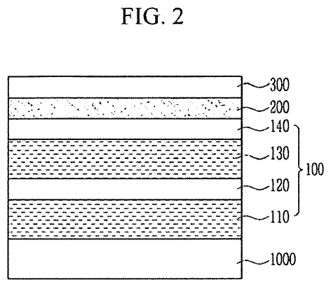

FIG. 2 shows a display device according to a comparative example. Referring to FIG. 2, a display device according to a comparative example does not include a shield layer 150. As shown in FIG. 2, a substrate 100, a LTPS layer 200, and a display layer 300 are sequentially stacked on a carrier substrate 1000

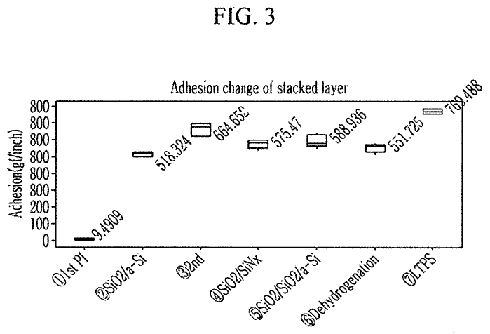

In a manufacturing process of each layer, adherence between the display device and the carrier substrate 1000 was measured, the results of which are shown in FIG. 3.

Referring to FIG. 3, adherence between the display device and the carrier substrate 1000 is not greatly increased in a process during which a first organic layer (PI) 110 that includes polyimide is stacked on the carrier substrate 1000. However, adherence between the carrier substrate 1000 and the first organic layer 110 that includes polyimide is significantly increased in a process for forming a first barrier layer (SiO₂/a-Si) 120.

This is because, as previously described, the plasma used in the PECVD process for forming the first barrier layer 120 changes an interface characteristic between the carrier substrate 1000 and the first organic layer 110, thereby causing an increase of adherence.

However, in the display device according to an exemplary embodiment of the present invention, the shield layer 150 is disposed between the first organic layer 110 and the first barrier layer 120 to prevent adherence between the display device and the carrier substrate 1000 from being increased, and to enable the display device to be easily separated from the carrier substrate 1000.

The following Table 1 shows measurements of adhesion in gram-force (gf) per inch between a carrier substrate 1000 and a display device according to Exemplary Embodiments 1, 2, and 3, each of which include a shield layer 150, and Comparative Example 1, which does not include a shield layer 150. Measurements of adhesion for Comparative Example 1 are shown for display devices including a first organic layer 110 that includes polyimide at thicknesses of 300 Å and 6000 Å. In Table 1, the shield layer 150 includes aluminum (Al) (Exemplary Embodiment 1), titanium nitride (TiN) (Exemplary Embodiment 2), and indium tin oxide (ITO) (Exemplary Embodiment 3), adhesion measurements for each of which are shown at thicknesses of 300 Å and 6000 Å.

TABLE 1
Thickness of the PI layer

| | Adhesion (gf/inch) | | | |
|---|---|---|---|---|
| | Comparative | | | |
| | Example 1 | Exemplary | Exemplary | Exemplary |
| | (Shield | Embodiment 1 | Embodiment 2 | Embodiment 3 |
| | layer not | (Al shield | (TiN shield | (ITO shield |
| (Å) | included) | layer included) | layer included) | layer included) |
| 300 | 629 | 5.01 | 4.57 | 6.94 |
| 6000 | 1087 | 5.56 | 6.33 | 6.46 |

Referring to Table 1, the shield layer 150, according to exemplary embodiments of the present invention, significantly reduced adherence of the carrier substrate 1000 to the display device as compared to the adherence of the first organic layer 110 including polyimide to the carrier substrate 1000 in Comparative Example 1.

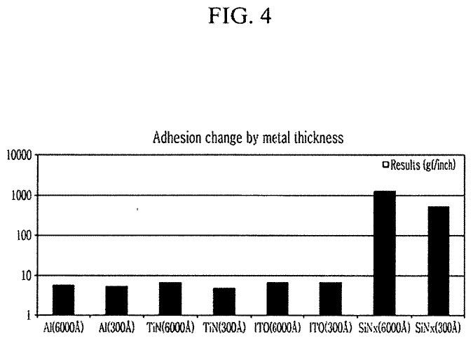

FIG. 4 shows adhesion measurements in gf/inch of the carrier substrate 1000 to display devices including the Al shield layer (Exemplary Embodiment 1), the TiN shield layer (Exemplary Embodiment 2), the ITO shield layer (Exemplary Embodiment 3), or the SiNx barrier layer (Comparative Example 1) at varying thicknesses thereof. Referring to FIG. 4, the display device has similar adherence when the thickness of the shield layer 150 is 300 Å as to when the thickness of the shield layer 150 is 6000 Å. Thus, it was determined that the adherence is not necessarily increased as the thickness of the shield layer 150 is increased, and adherence can be excellently reduced even when the shield layer has a thin thickness. When the thickness of the shield layer 150 is thin, adherence can be sufficiently reduced, and accordingly, adherence can be reduced without increasing the entire thickness of the substrate 100.

When the thickness of the substrate 100 is increased, a flexible characteristic of the display device may be affected. Accordingly, the shield layer 150 has a thin thickness. For example, the shield layer 150 may have a thickness of about 300 Å to about 6000 Å, and when the thickness of the shield layer 150 is 300 Å to 450 Å, adherence can be effectively reduced while maintaining the shield layer 150 with a thin thickness.

As described herein, according to exemplary embodiments of the present invention, the shield layer 150 reduces adherence between the carrier substrate 1000 and the display device, such that the display device can be easily detached from the carrier substrate 1000.

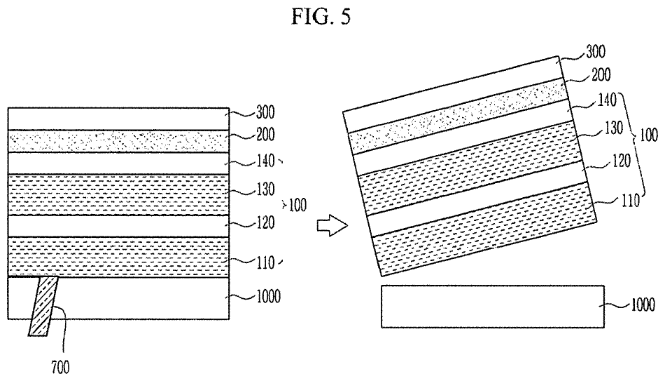

FIG. 5 shows a process for separating the display device according to the comparative example shown in FIG. 2. In the case of the display device according to the comparative example of the present invention shown in FIG. 2, adherence between the carrier substrate 1000 and the display device is about 600 gf/inch or more. Thus, a laser beam 700 is used to separate the display device from the carrier substrate 1000, as shown in FIG. 5. A laser beam having a wavelength of about 300 nm is emitted from a lower portion of the carrier substrate 1000 toward an interface of the first organic layer 110 and the carrier substrate 110, and the first organic layer 110 is separated from the carrier substrate 1000 while being carbonized by energy of the laser beam 700. Thus, as shown in FIG. 5, the display device is detached from the carrier substrate 1000.

However, in the display device according to an exemplary embodiment of the present invention, the shield layer 150 is disposed in the substrate 100 to reduce adherence between the carrier substrate 1000 and the display device. Accordingly, the display device can be separated from the carrier substrate 1000 without performing a laser irradiation process.

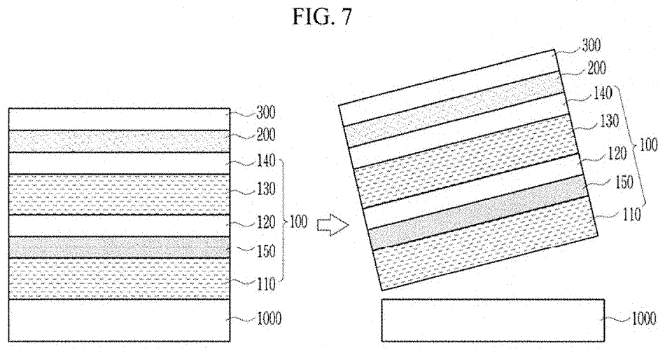

FIG. 6 and FIG. 7 show a manufacturing process of a display device according to an exemplary embodiment of the present invention. Referring to FIG. 6, a first organic layer 110 and a shield layer 150 are sequentially stacked on a carrier substrate 1000. Next, a first barrier layer 120 is deposited by using a PECVD method, and then a second organic layer 130 is deposited on the first barrier layer 120 by using the PECVD method. Next, a second barrier layer 140 and a LTPS layer 200 and a display layer 300 are sequentially formed.

FIG. 7 shows a process for separating the carrier substrate 1000 from the display device according to an exemplary embodiment of the present invention. Referring to FIG. 7, the display device can be separated from the carrier substrate 1000 without performing a laser irradiation process. This is because, as shown in Table 1, adherence between the carrier substrate 1000 and the display device is reduced due to the inclusion of the shield layer 150. For example, in the case of the manufacturing method shown in FIG. 5, which is a comparative example, an additional laser irradiation process was required, but the present exemplary embodiment is economical because a laser irradiation process can be omitted.

For example, according to the display device and the manufacturing method of the display device according to an exemplary embodiment of the present invention, the shield layer 150 is disposed between the first organic layer 110 and the first barrier layer 120 of the substrate 100. Thus, the display device can be easily separated from the carrier substrate 1000, which is used during a manufacturing process, while reducing adherence between the carrier substrate 1000 and the display device.

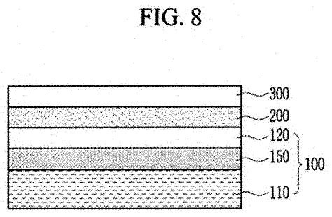

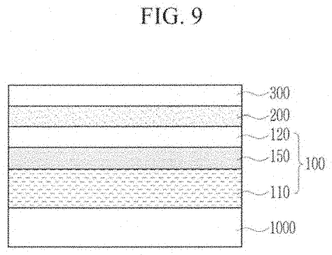

FIG. 8 shows a cross-section of a display device according to an exemplary embodiment of the present invention. FIG. 9 shows a cross-section of a display device attached to a carrier substrate 1000 according to an exemplary embodiment of the present invention.

Referring to FIG. 8 and FIG. 9, a display device according an exemplary embodiment of the present invention is the same as the display device of FIGS. 1 and 6, except that a substrate 100 according to the present embodiment includes only a first organic layer 110, a shield layer 150, and a first barrier layer 120. A detailed description of previously described elements is omitted for brevity. The display device of the exemplary embodiment of the present invention according to FIG. 1 includes first and second organic layers 110 and 130 and first and second barrier layers 120 and 140, but the display device according to the present exemplary embodiment of the present invention includes only the first organic layer 110 and the first barrier layer 120. Thus, the thickness of the substrate 100 can be reduced, and the thickness of the entire display device can be reduced.

FIG. 9 shows a cross-section of the display device shown in FIG. 8 attached to a carrier substrate 1000 during a manufacturing process. As shown in FIG. 9, the display device formed on a carrier substrate 1000 can be detached from the carrier substrate 1000 without carrying out additional laser irradiation by using the method shown in FIG. 7.

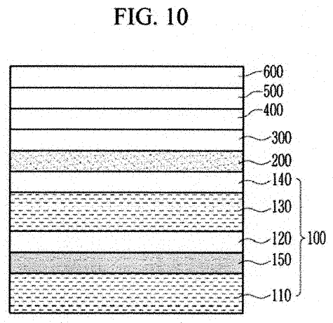

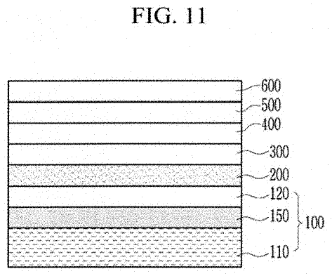

FIG. 10 and FIG. 11 show cross-sections of display devices according to exemplary embodiments of the present invention. The display devices of FIG. 10 and FIG. 11 are the same as the display devices according to the exemplary embodiments of FIG. 1 and FIG. 8, respectively, except that the display devices of FIG. 10 and FIG. 11 include a touch sensing layer 400, a polarization layer 500, and a window layer 600. A detailed description of previously described elements is omitted for brevity. In FIG. 10 and FIG. 11, the window layer 600 may be omitted. The touch sensing layer 400 is configured to sense an externally applied touch input detected by a plurality of touch sensors. The polarization layer 500 lets only light of a specific plane of vibration pass through. The touch sensing layer 400 or the polarization layer 500 may be omitted according to exemplary embodiments of the present invention. For example, the display device according to an exemplary embodiment of the present invention may include only the touch sensing layer 400 or only the polarization layer 500.

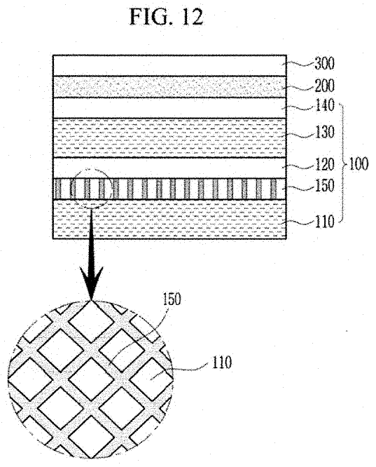

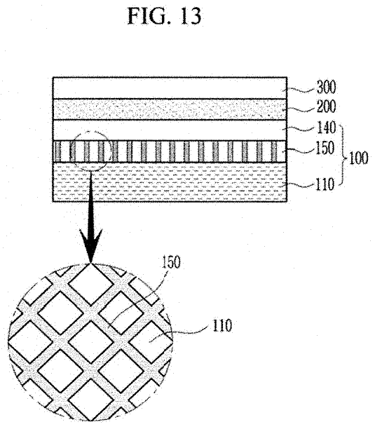

FIG. 12 and FIG. 13 show display devices according to exemplary embodiments of the present invention. The display devices according to the exemplary embodiments of the present invention illustrated in FIG. 12 and FIG. 13 are the same as the display devices illustrated in FIG. 1 and FIG. 8, respectively, except for a shape of the shield layer 150. A detailed description of previously described elements is omitted for brevity.

Referring to FIG. 12 and FIG. 13, the shield layer 150 of the display devices, according to the exemplary embodiments of the present invention, have a lattice shape. For example, in the case of the display device according to the exemplary embodiments of the present invention illustrated in FIG. 1 and FIG. 8, the shield layer 150 is formed in the shape of a whole plate that covers the entire surface of the first organic layer 110. However, the shield layer 150 of the display devices according to the exemplary embodiments of FIG. 12 and FIG. 13 have a net structure that covers a part of the first organic layer 110. Accordingly, as shown in FIG. 12 and FIG. 13, some parts of the first organic layer 110 are exposed without being overlapped with the shield layer 150.

Even when the shield layer 150 has the net structure and thus is patterned, an increase of adherence between the display device and a carrier substrate 1000 can be prevented by the inclusion of the shield layer 150. This is because the shield layer 150 of the lattice structure sufficiently blocks the influence of the plasma used in the formation of the first barrier layer 120. Thus, when the shield layer 150 is formed in a lattice shape, the flexibility of the substrate 100 can be further enhanced.

While the present invention has been shown and described with reference to exemplary embodiments thereof, it should be understood by those of ordinary skill in the art that various modifications may be made thereto without departing from the spirit and scope of the present invention as defined by the appended claims.

What is claimed is:

1. A display device, comprising:
a substrate including a first organic layer and a first barrier layer; and
a shield layer disposed between the first organic layer and the first barrier layer,
wherein the shield layer includes a metal.

2. The display device of claim 1, wherein the shield layer has a thickness of about 300 Å to about 6000 Å.

3. The display device of claim 1, wherein the shield layer comprises Al, TiN, Ti, Mo, and/or Cu.

4. The display device of claim 1, wherein the first organic layer comprises polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and/or an ethylene-vinyl alcohol copolymer.

5. The display device of claim 1, wherein the first barrier layer comprises SiOx, SiNx, a-Si, a-SiC, and/or Al₂O₃.

6. The display device of claim 1, wherein the shield layer overlaps an entire surface of the first organic layer.

7. The display device of claim 1, wherein the shield layer has a lattice shape, and at least a portion of the first organic layer does not overlap the shield layer.

8. The display device of claim 1, wherein the substrate further comprises:
a second organic layer disposed on the first barrier layer, and
a second barrier layer disposed on the second organic layer.

9. The display device of claim 8, wherein the second organic layer includes polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and/or an ethylene-vinyl alcohol copolymer, and
the second barrier includes SiOx, SiNx, a-Si, a-SiC, and/or Al₂O₃.

10. A display device, comprising:
a substrate including a first organic layer and a first barrier layer,
a display layer disposed on the substrate; and
a shield layer disposed between the first organic layer and the first barrier layer,
wherein the shield layer includes a metal oxide, and
wherein a thickness of the shield layer is about 300 Å to about 450 Å.

11. The display device of claim 10, wherein the shield layer comprises ITO, IZO, IZTO, ATO, AZO, GZO, FTO, ZTO, ZnO, FZO, and/or IGZO.

12. The display device of claim 10, wherein the first organic layer comprises polyimide, polyacrylate, polyethylene terephthalate, polyethylene naphthalate, polycarbonate, polyarylate, polyether imide, polyether sulfone, cellulose triacetate, polyvinylidene chloride, polyvinylidene fluoride, and/or an ethylene-vinyl alcohol copolymer, and
wherein the first barrier layer comprises SiOx, SiNx, a-Si, a-SiC, and/or Al₂O₃.

13. The display device of claim 10, wherein the shield layer overlaps an entire surface of the first organic layer.

14. The display device of claim 10, wherein the shield layer has a lattice shape, and at least a portion of the first organic layer does not overlap the shield layer.

15. The display device of claim 10, wherein the substrate further comprises:
a second organic layer disposed on the first barrier layer; and
a second barrier layer disposed on the second organic layer.

16. A method for manufacturing a display device, comprising:
forming a first organic layer on a carrier substrate;
forming a shield layer on the first organic layer;
forming a first barrier layer on the shield layer, and
separating the carrier substrate from the first organic layer,
wherein the shield layer includes a metal or a metal oxide.

17. The method for manufacturing the display device of claim 16, wherein the shield layer includes a metal, and a thickness of the shield layer is about 300 Å to about 6000 Å.

18. The method for manufacturing the display device of claim 16, wherein the shield layer includes a metal oxide, and a thickness of the shield layer is about 300 Å to about 450 Å.

19. The method for manufacturing the display device of claim 16, wherein in the separation of the carrier substrate and the first organic layer, a laser irradiation process is not carried out.

20. The method for manufacturing the display device of claim 16, wherein the forming of the first barrier layer on the shield layer comprises carrying out a plasma-enhanced chemical vapor deposition (PECVD) process.
